(19) United States
(12) Patent Application Publication
(10) Pub. No.: US 2026/0068218 A1
(43) Pub. Date: Mar. 5, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hiroki SAKATA, Kawasaki Kanagawa (JP)

(21) Appl. No.: 19/053,001

(22) Filed: Feb. 13, 2025

(30) Foreign Application Priority Data
Sep. 3, 2024 (JP) 2024-151356

(51) Int. Cl. H10D 30/66; H10D 30/01; H10D 62/10; H10D 64/00; H10D 64/64

(52) U.S. Cl. CPC H10D 30/668; H10D 30/665; H10D 62/102; H10D 64/117; H10D 64/647; H10D 30/0295; H10D 30/0297

(57) ABSTRACT

A semiconductor device includes a semiconductor member, a drain electrode, a gate electrode, a source electrode, and an insulating film. The semiconductor member is provided with a first groove and a second groove. The gate electrode is disposed inside the first groove. The source electrode is disposed inside the second groove. The insulating film is provided on an inner surface of the second groove. The insulating film contains negative fixed charges. A first semiconductor region of the semiconductor member has first conductivity type impurities. A second semiconductor region of the semiconductor member has a higher concentration of the first conductivity type impurities. The second semiconductor region is located on the upper side of the first semiconductor region. The source electrode can form a Schottky junction with the first semiconductor region. The source electrode can form an ohmic junction with the second semiconductor region.

### CROSS-REFERENCE TO RELATED APPLICATION

This application is based upon and claims the benefit of priority from Japanese Patent Application No. 2024-151356, filed on Sep. 3, 2024, the entire contents of which are incorporated herein by reference.

### FIELD

Embodiments described herein relate generally to a semiconductor device.

### BACKGROUND

There are semiconductor devices such as metal oxide semiconductor field effect transistors (MOSFETs) that can achieve an off state by promoting depletion of a semiconductor region through a Schottky junction. This structure has a problem that it is difficult to increase a gate threshold voltage.

### BRIEF DESCRIPTION OF THE DRAWINGS

FIG. 1 is a schematic cross-sectional view of a semiconductor device of an embodiment.

FIG. 2 is a partially schematic view of the semiconductor device of a first comparative example.

FIG. 3 is a partially schematic view of a semiconductor device of a second comparative example.

FIG. 4 is a graph showing simulation results of transfer characteristics of the semiconductor device according to the embodiment and the first and second comparative examples.

### DETAILED DESCRIPTION

A semiconductor device of an embodiment includes a semiconductor member, a drain electrode, a gate electrode, a source electrode, and an insulating film. The semiconductor member is provided with a first groove and a second groove. The first groove and the second groove extend in a first direction. The first groove and the second groove are aligned in a second direction intersecting with the first direction. The first groove and the second groove are recessed on a first side in a third direction intersecting with both the first direction and the second direction. The drain electrode is located on the first side of the semiconductor member in the third direction. The gate electrode is disposed inside the first groove. The source electrode is disposed inside the second groove. The insulating film is provided on at least a part of the inner surface of the second groove. The insulating film contains negative fixed charges. The semiconductor member is provided with a first semiconductor region and a second semiconductor region. The first semiconductor region has first conductivity type impurities. The second semiconductor region has a higher concentration of the first conductivity type impurities than the first conductivity type impurities of the first semiconductor region. The second semiconductor region is located on a second side of the first semiconductor region in the third direction. The source electrode can form a Schottky junction with the first semiconductor region. The source electrode can form an ohmic junction with the second semiconductor region. At least a part of the first semiconductor region is located between the gate electrode and the source electrode in the second direction. The insulating film is sandwiched between the source electrode and the part of the first semiconductor region in the second direction.

Hereinafter, the semiconductor device of the embodiment will be described with reference to the drawings.

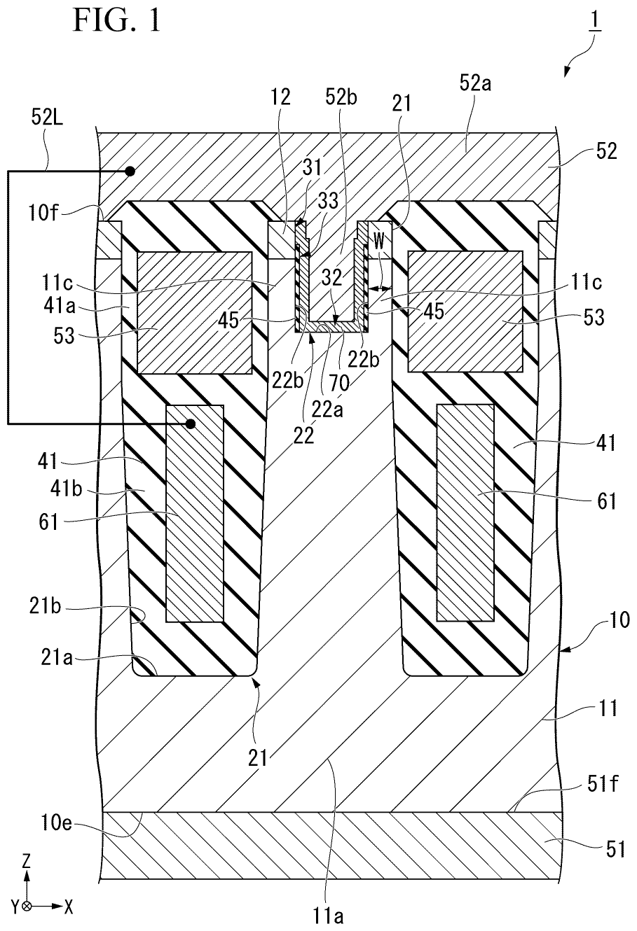

FIG. 1 is a schematic cross-sectional view of a semiconductor device 1 of the embodiment.

In the drawings, an X axis, a Y axis, and a Z axis are shown appropriately. The X axis, the Y axis, and the Z axis are orthogonal to each other.

In this specification, a “direction” is defined as a vector that includes the concepts of positive and negative directions parallel to a particular axis. Therefore, the “direction” is a concept that encompasses two directions (a first side and a second side) that face opposite each other. In the following embodiments, a direction parallel to the Y axis corresponds to a “first direction”, a direction parallel to the X axis corresponds to a “second direction intersecting with the first direction”, and a direction parallel to the Z axis corresponds to a “third direction intersecting with both the first and second directions”. Moreover, in the following embodiments, the side (−Z) of the third direction Z opposite to the side in which the Z-axis arrow points is called the lower side or a first side of the third direction, and the side (+Z) of the third direction Z toward which the Z-axis arrow points is called the upper side or a second side of the third direction. Furthermore, in this specification, the concepts of “upper” and “lower” are not necessarily terms that indicate a relationship with the direction of gravity.

As shown in FIG. 1, the semiconductor device 1 according to the embodiment includes a semiconductor member 10, a drain electrode (first electrode) 51, a source electrode (second electrode) 52, a gate electrode (third electrode) 53, a field plate (conductive member) 61, an insulating member 41, and an insulating film 45. In this specification, the thickness direction of the semiconductor device 1 (that is, the direction from the drain electrode 51 toward the source electrode 52) is the third direction Z.

The semiconductor device 1 of this embodiment is a trench-type metal-oxide-semiconductor field-effect transistor (MOSFET). Further, the semiconductor device 1 of this embodiment is a Schottky contact transistor. The semiconductor device 1 can control the depletion of the semiconductor region of the semiconductor member 10 by the potential of the gate electrode 53. That is, the semiconductor device 1 can control a current flowing between the drain electrode 51 and the source electrode 52 by the potential of the gate electrode 53.

The semiconductor member 10 contains at least one selected from the group consisting of, for example, silicon (Si), a nitride semiconductor (such as GaN), silicon carbide (SiC), and an oxide semiconductor (such as GaO).

The semiconductor member 10 is provided with a plurality of gate electrode grooves (first grooves) 21 and a plurality of source electrode grooves (second grooves) 22. The gate electrode grooves 21 and the source electrode grooves 22 are recessed downward (toward a first side in the third direction Z) from an upper surface 10f of the semiconductor member 10. The gate electrode grooves 21 and the source electrode grooves 22 extend in the first direction Y and are arranged alternately in the second direction X. Therefore, the gate electrode grooves 21 are provided on both sides of the source electrode groove 22 in the second direction X.

The gate electrode groove 21 has an inner surface provided with a bottom 21a facing upward and a pair of side wall portions 21b facing each other in the second direction X. Similarly, the source electrode groove 22 has an inner surface provided with a bottom 22a facing upward and a pair of side wall portions 22b facing each other in the second direction X. The gate electrode groove 21 is formed to be deeper than the source electrode groove 22. That is, the bottom 21a of the gate electrode groove 21 is located lower than the bottom 22a of the source electrode groove 22. Further, the width dimension of the gate electrode groove 21 is larger than the width dimension of the source electrode groove 22. Furthermore, in the following description, the width dimension means the dimension in the second direction X.

The semiconductor member 10 includes a first semiconductor region 11 and a second semiconductor region 12. The first semiconductor region 11 and the second semiconductor region 12 are both n-type semiconductors. When the semiconductor member 10 contains silicon, the first conductivity type impurity can be, for example, a pentavalent element such as phosphorus or arsenic. That is, the first conductivity type impurity is an n-type impurity. The first semiconductor region 11 and the second semiconductor region 12 are formed by doping a pentavalent element as an impurity in the semiconductor member 10 containing silicon and diffusing the element. Further, the second semiconductor region 12 has a higher concentration of impurities diffused therein than the first semiconductor region 11. The first semiconductor region 11 is, for example, an n-layer. The second semiconductor region 12 is an n layer or an n+ layer. In this embodiment, the semiconductor member 10 does not include a p-type semiconductor. Therefore, the process of manufacturing the semiconductor device 1 can be simplified.

The first semiconductor region 11 includes a drift region 11a and a cell region 11c. The drift region 11a is a region in the first semiconductor region 11 below the lower end of the source electrode 52 (that is, a lower end of a contact portion 52b described later). The lower end of the drift region 11a contacts an upper surface 51f of the drain electrode 51. Further, the cell region 11c is located on the upper side of the drift region 11a. The cell region 11c is a region sandwiched between the gate electrode groove 21 and the source electrode groove 22.

The cell region 11c is a region between the gate electrode groove 21 and the source electrode groove 22 in the first semiconductor region 11. That is, the cell region 11c is located between the source electrode 52 and the gate electrode 53 in the second direction X. The cell region 11c is located at the upper end of the first semiconductor region 11. The width dimension W of the cell region 11c is, for example, 25 nm or more and 100 nm or less.

The second semiconductor region 12 is formed to a certain depth from the upper surface 10f of the semiconductor member 10. The second semiconductor region 12 is provided on the upper side of the first semiconductor region 11. The second semiconductor region 12 contacts the cell region 11c of the first semiconductor region 11. The second semiconductor region 12 is located on the upper side of the bottom 21a of the gate electrode groove 21 and the bottom 22a of the source electrode groove 22. Therefore, the second semiconductor region 12 is divided in the second direction X by the gate electrode groove 21 and the source electrode groove 22. The width dimension of the second semiconductor region 12 is substantially the same as the width dimension W of the cell region 11c.

Each of the drain electrode 51, the source electrode 52, the gate electrode 53, and the field plate 61 extends in the first direction Y. The gate electrode 53 and the source electrode 52 are aligned in the second direction X. The gate electrode 53 and the field plate 61 are aligned in the third direction Z.

The drain electrode 51 is provided on a lower surface 10e of the semiconductor member 10. The drain electrode 51 contains, for example, Al, Cu, Mo, W, Ta, Co, Ru, Ti, and Pt.

At least a part of the source electrode 52 is disposed inside the source electrode groove 22. The source electrode 52 includes an electrode portion 52a, a contact portion (metal portion) 52b, and a metal film 70. The electrode portion 52a is located on the upper side of the upper surface 10f of the semiconductor member 10. The electrode portion 52a is provided on the upper side of the contact portion 52b and the insulating member 41. The contact portion 52b is disposed inside the source electrode groove 22. The electrode portion 52a and the contact portion 52b include, for example, Al, Cu, Mo, W, Ta, Co, Ru, Ti, and Pt.

The metal film 70 is made of, for example, a metal material different from the electrode portion 52a and the contact portion 52b. The metal material constituting the metal film 70 has a work function higher than that of the first semiconductor region 11.

Therefore, the metal film 70 can form a Schottky junction with the first semiconductor region 11. In this specification, the portion where the metal film 70 and the first semiconductor region 11 form a Schottky junction is called a Schottky junction portion 32. In this embodiment, the Schottky junction portion 32 is provided in the bottom 22a of the source electrode groove 22. Furthermore, in this specification, when work functions of a plurality of sites are compared, the energy levels of the sites are compared.

The metal material constituting the metal film 70 has a work function lower than of that the second semiconductor region 12. Therefore, the metal film 70 can form an ohmic junction with the second semiconductor region 12. In this specification, the portion where the metal film 70 and the second semiconductor region 12 form an ohmic junction is called an ohmic junction portion 31. In this embodiment, the ohmic junction portion 31 is provided at the upper end (the end on the second side in the third direction Z) of the side wall portion 22b of the source electrode groove 22.

In one example, when the semiconductor member 10 contains silicon, the metal film 70 that enables a Schottky junction and an ohmic junction contains at least one selected from the group consisting of, for example, Ti, W, Mo, Ta, Zr, Al, Sn, V, Re, Os, Ir, Pt, Pd, Rh, Ru, Nb, Sr, and Hf.

In the source electrode 52 of this embodiment, the metal film 70 having a work function higher than that of the first semiconductor region 11 is formed on the surface of the contact portion 52b. However, the source electrode 52 may be entirely made of a metal material having a work function higher than that of the first semiconductor region 11. In this case, the metal film 70 may be omitted.

The gate electrode 53 is disposed inside the gate electrode groove 21. The lower end of the gate electrode 53 is located on the lower side of the lower end of the contact portion 52b. The upper end of the gate electrode 53 and the second semiconductor region 12 overlap with each other in the second direction X. The upper end of the gate electrode 53 is located on the lower side of the upper end of the contact portion 52b. In the gate electrode groove 21, the insulating member 41 is interposed between the first semiconductor region 11 and the gate electrode 53. That is, the insulating member 41 insulates the semiconductor member 10 and the gate electrode 53 from each other in the gate electrode groove 21. The gate electrode 53 faces the surface of the cell region 11c of the first semiconductor region 11 via the insulating member 41 in the second direction X. The gate electrode 53 contains, for example, polysilicon.

The field plate 61 is disposed inside the gate electrode groove 21. The field plate 61 is located on the lower side of the gate electrode 53. The width dimension of the field plate 61 (the dimension in the second direction X) is smaller than the width dimension of the gate electrode 53. In the gate electrode groove 21, the insulating member 41 is interposed between the field plate 61 and the gate electrode 53. Therefore, the field plate 61 and the gate electrode 53 are insulated from each other. Further, in the gate electrode groove 21, the insulating member 41 is interposed between the first semiconductor region 11 and the field plate 61. That is, the insulating member 41 insulates the semiconductor member 10 and the field plate 61 from each other in the gate electrode groove 21.

The insulating member 41 is disposed inside the gate electrode groove 21. The insulating member 41 includes a gate insulating film 41a and a field plate insulating film 41b. The gate insulating film 41a is located between the first semiconductor region 11 and the gate electrode 53. On the other hand, the field plate insulating film 41b is located between the first semiconductor region 11 and the field plate 61.

The field plate 61 is electrically connected to the source electrode 52. The field plate 61 and the source electrode 52 are electrically connected by, for example, a wiring 52L. Accordingly, the field plate 61 and the source electrode 52 have the same potential. Furthermore, the field plate 61 may be extended to the upper surface of the semiconductor device 1 at a location not shown in the figure and electrically connected to the source electrode 52.

By providing the field plate 61 in the gate electrode groove 21, the electric field strength in the drift region 11a can be reduced. Accordingly, the withstand voltage characteristics between the drain electrode 51 and the source electrode 52 of the semiconductor member 10 can be improved. Further, as the breakdown voltage is improved, the impurity concentration of the drift region 11a can be set high, and the on-resistance of the semiconductor device 1 can be reduced.

The insulating film 45 is formed on an inner surface of the source electrode groove 22. The thickness of the insulating film 45 is, for example, 1 nm or more and 30 nm or less. The insulating film 45 is, for example, silicon oxide (SiO₂), aluminum oxide (Al₂O₃), or gallium oxide (Ga₂O₃). Further, the insulating film 45 may be made of other materials as long as they have insulating properties.

The insulating film 45 of this embodiment contains negative fixed charges. When the insulating film 45 contains a metal oxide, the negative fixed charges are, for example, defects caused by complex vacancies at the bonding portions of metal atoms and oxygen atoms. The amount of negative fixed charges added to the insulating film 45 is preferably 10¹² cm⁻² or more and 10¹⁴ cm⁻² or less.

The insulating film 45 of this embodiment is formed on the inner surface of the source electrode groove 22 excluding the upper end of the side wall portion 22b and the bottom 22a. That is, the insulating film 45 is not formed on the upper end of the side wall portion 22b and the bottom 22a.

The second semiconductor region 12 is provided in the upper end of the semiconductor member 10. Therefore, in the inner surface of the source electrode groove 22, the upper end of the side wall portion 22b exposes the second semiconductor region 12. Further, in the semiconductor member 10, the second semiconductor region 12 is located on the upper side of the bottom 22a of the source electrode groove 22, and the first semiconductor region 11 is provided on the lower side of the second semiconductor region 12. Therefore, in the inner surface of the source electrode groove 22, the bottom 22a exposes the first semiconductor region 11. Further, the metal film 70 of the source electrode 52 is formed along the entire inner surface of the source electrode groove 22 including the bottom 22a. Therefore, the metal film 70 is in direct contact with the semiconductor member 10 at the bottom 22a and the upper end of the side wall portion 22b of the inner surface of the source electrode groove 22, and is in contact with the insulating film 45 at the other portions (that is, the regions other than the upper end of the side wall portion 22b). The metal film 70 contacts the second semiconductor region 12 at the upper end of the side wall portion 22b to form the ohmic junction portion 31. Further, the metal film 70 contacts the first semiconductor region 11 at the bottom 22a to form the Schottky junction portion 32.

The insulating film 45 covers the entire portion of the source electrode 52 that faces the gate electrode 53 in the second direction X. That is, the upper end of the insulating film 45 is disposed on the upper side of either the upper end of the contact portion 52b or the upper end of the gate electrode 53, whichever is located on the lower side in the third direction Z (the upper end of the gate electrode 53 in this embodiment), or disposed at the same position as either the upper end of the contact portion 52b or the upper end of the gate electrode 53, whichever is located on the lower side in the third direction Z. Similarly, the lower end of the insulating film 45 is disposed on the lower side of either the lower end of the source electrode 52 (the lower end of the contact portion 52b in this embodiment) or the lower end of the gate electrode 53, whichever is located on the upper side in the third direction Z (the lower end of the source electrode 52 in this embodiment), or disposed at the same position as either the lower end of the source electrode 52 or the lower end of the gate electrode 53, whichever is located on the upper side in the third direction Z.

According to this embodiment, the insulating film 45 is disposed between the metal film 70 having a high work function and the semiconductor member 10. Therefore, the metal film 70, the insulating film 45, and the first semiconductor region 11 of the semiconductor member 10 form a metal-insulator-semiconductor (MIS) type junction. In this specification, the portion where the metal film 70, the insulating film 45, and the first semiconductor region 11 form an MIS junction is referred to as an MIS junction portion 33. In this embodiment, the MIS junction portion 33 is provided in the side wall portion 22b of the source electrode groove 22.

Next, a method of manufacturing the semiconductor device 1 of this embodiment will be described.

In the method of manufacturing the semiconductor device 1 of this embodiment, first, the semiconductor member 10 containing n-type impurities throughout (that is, the semiconductor member 10 having the first semiconductor region 11 formed throughout) is prepared. Next, the gate electrode groove 21 and the source electrode groove 22 are formed in the semiconductor member 10. The step of forming the gate electrode groove 21 and the source electrode groove 22 can employ, for example, reactive ion etching (RIE).

In the method of manufacturing the semiconductor device 1 of this embodiment, next, the field plate 61 and the gate electrode 53 embedded in the insulating member 41 are formed inside the gate electrode groove 21. The step of forming the insulating member 41, the field plate 61, and the gate electrode 53 is performed by repeating the steps of forming the insulating member 41, forming a groove portion in the insulating member 41, and forming a conductive member in the groove portion.

In the method of manufacturing the semiconductor device 1 of this embodiment, next, the insulating film 45, the metal film 70, and the contact portion 52b are formed inside the source electrode groove 22. In this step, first, the insulating film 45 is formed on the entire inner surface of the source electrode groove 22 including the bottom 22a. The insulating film 45 is formed by, for example, chemical vapor deposition (CVD). Next, the insulating film 45 is partially masked and the insulating film 45 provided on the upper end of the side wall portion 22b and the bottom 22a is removed. The insulating film 45 is removed by means of, for example, reactive ion etching. Furthermore, a negative fixed charge is introduced into the insulating film 45. Furthermore, when the insulating film 45 contains aluminum oxide, the atmosphere during film formation is controlled so as not to mix nitrogen elements into the insulating film 45, which makes it easier to cause fixed charges to remain in the insulating film 45. Furthermore, when the insulating film 45 contains gallium oxide, the content of fixed charges in the insulating film 45 can be adjusted by performing a hydrogen annealing treatment after the film is formed. Next, the metal film 70 is formed along the entire inner surface of the source electrode groove 22 including the bottom 22a. The metal film 70 is formed by, for example, chemical vapor deposition (CVD) or atomic layer deposition (ALD). Next, the contact portion 52b is formed inside the groove portion.

Next, the second semiconductor region 12 is formed in the upper portion of the semiconductor member 10 by diffusing impurities into the upper portion of the semiconductor member 10. Furthermore, the electrode portion 52a is formed on the upper side of the semiconductor member 10. Further, the drain electrode 51 is formed on the lower side of the semiconductor member 10. In this way, the semiconductor device 1 can be obtained.

Next, the operating principle of the semiconductor device 1 of this embodiment will be described.

In this embodiment, since the work function of the metal film 70 is higher than the work function of the first semiconductor region 11, a depletion layer is formed in the cell region 11c. When no voltage is applied to the gate electrode 53, the depletion layer provides an off state in which no current flows through the cell region 11c. By controlling the potential of the gate electrode 53, an electron accumulation layer is formed as a channel in the cell region 11c, and an on state in which a drain current flows in the cell region 11c is obtained. Therefore, in the semiconductor device 1, the current between the drain electrode 51 and the source electrode 52 is controlled by the potential of the gate electrode 53. Furthermore, the potential of the gate electrode 53 is a potential based on the potential of the source electrode 52.

In this embodiment, the metal film 70 is in ohmic contact with the second semiconductor region 12 at the upper end of the source electrode groove 22 to form the ohmic junction portion 31. In the on state, a current passing through a channel formed in the cell region 11c flows through the ohmic junction portion 31 to the source electrode 52.

In this embodiment, the metal film 70 forms a Schottky junction portion 32 with the first semiconductor region 11 at the bottom 22a of the source electrode groove 22. Therefore, the boundary portion between the metal film 70 and the first semiconductor region 11 functions as a diode (body diode), so that a current can flow in the forward direction.

In this embodiment, the insulating film 45 contains negative fixed charges. Accordingly, the band of the first semiconductor region 11 is raised, and the Schottky barrier can be made higher. Accordingly, the depletion of the cell region 11c becomes significant, and it becomes impossible to pass a current through the cell region 11c (that is, to turn on the cell region 11c) unless a large voltage is applied to the cell region 11c from the gate electrode 53. That is, according to this embodiment, since the insulating film 45 contains negative fixed charges, it is possible to increase the gate threshold voltage.

Particularly, in this embodiment, the insulating film 45 covers the entire cell region 11c between the gate electrode groove 21 and the source electrode groove 22 from the second direction X. Therefore, the negative fixed charges contained in the insulating film 45 raise the band of the entire cell region 11c, and the entire depletion of the cell region 11c can be promoted. As a result, it becomes difficult for a current to flow through the cell region 11c in the off state, and the gate threshold voltage can be further increased.

The operations and effects of the semiconductor device 1 of this embodiment and semiconductor devices C1 and C2 of comparative examples will be compared.

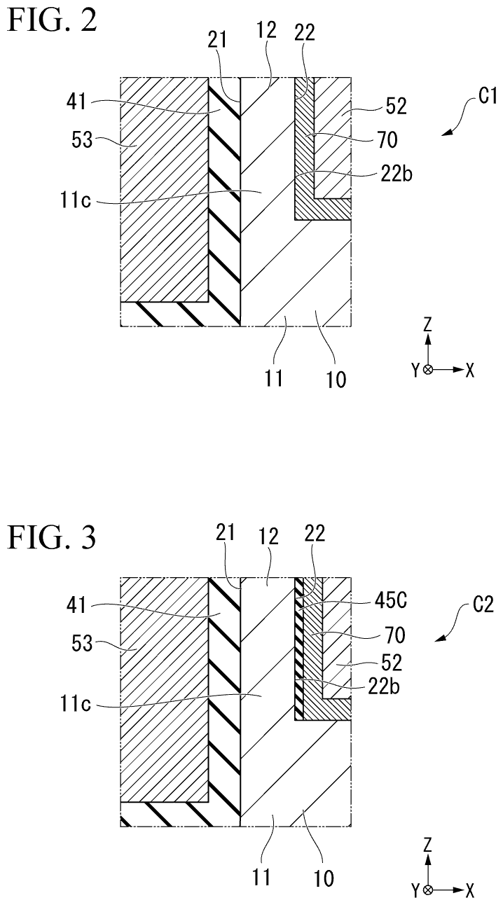

FIGS. 2 and 3 are partially enlarged views in the vicinity of the cell region 11c of the semiconductor devices C1 and C2 of the comparative examples. Furthermore, in FIGS. 2 and 3, the same components as those in the semiconductor device 1 of the embodiment are denoted by the same reference numerals and a description thereof will be omitted.

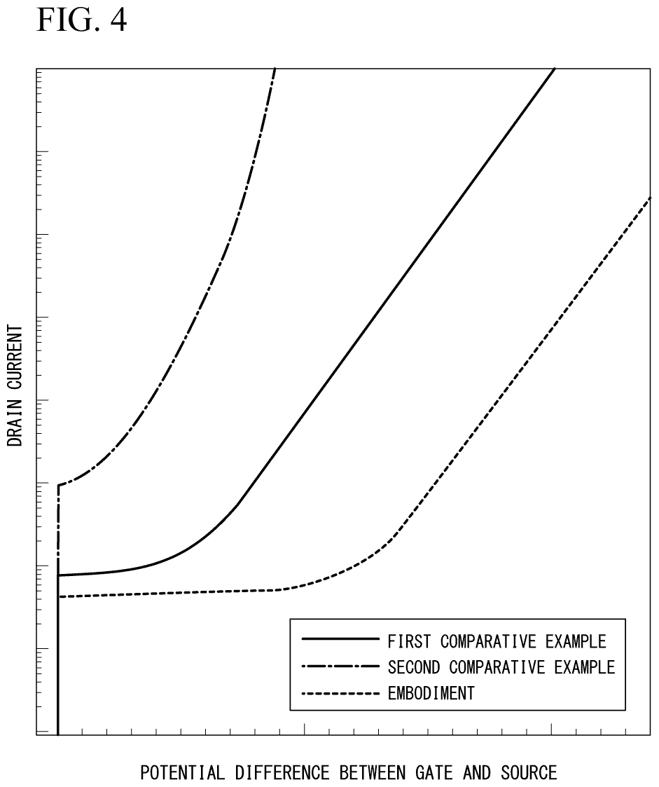

FIG. 4 is a graph showing simulation results of the transfer characteristics of the semiconductor device 1 of the embodiment, the semiconductor device C1 of the first comparative example, and the semiconductor device C2 of the second comparative example. That is, FIG. 4 shows a change in drain current when the voltage between the drain electrode 51 and the source electrode 52 is kept constant and the voltage between the gate electrode 53 and the source electrode 52 is changed. The horizontal axis of FIG. 4 represents the potential difference between the gate electrode 53 and the source electrode 52, and the vertical axis represents the current flowing through the drain electrode 51. Further, FIG. 4 is a semi-logarithmic graph in which the vertical axis is logarithmic.

The semiconductor device C1 of the first comparative example shown in FIG. 2 does not have the insulating film 45 compared to the semiconductor device 1 of the embodiment. In the semiconductor device C1 of the first comparative example, the metal film 70 having a high work function is in direct contact with the cell region 11c of the first semiconductor region 11 to form a Schottky junction. Accordingly, in the semiconductor device C1 of the first comparative example, the depletion of the portion along the side wall portion 22b of the source electrode groove 22 in the cell region 11c is promoted, and the current flow is promoted, so that the current is unlikely to flow. However, in the semiconductor device C1 of the first comparative example, the degree of depletion of the cell region 11c depends on the work function of the metal film 70. Therefore, in the semiconductor device C1 of the first comparative example, there is a limit to the depletion of the cell region 11c, and the gate threshold voltage is unlikely to sufficiently increase.

The semiconductor device C2 of the second comparative example shown in FIG. 3 includes an insulating film 45C that does not have fixed charges compared to the semiconductor device C1 of the first comparative example. The semiconductor device C2 of the second comparative example is different from the semiconductor device 1 of the embodiment in that the insulating film 45C does not contain fixed charges. In the semiconductor device C2 of the second comparative example, since the cell region 11c and the metal film 70 are separated by the thickness of the insulating film 45C and are insulated from each other, no charge transfer occurs, and therefore depletion of the cell region 11c is unlikely to progress. Therefore, in the semiconductor device C2 of the second comparative example, since a current flows more easily through the cell region 11c than in the semiconductor device C1 of the first comparative example, the gate threshold voltage decreases.

In this way, the gate threshold voltage is unlikely to increase in the semiconductor device C1 of the first comparative example, and the gate threshold voltage is more unlikely to increase in the semiconductor device C2 of the second comparative example. Further, the semiconductor device C1 of the first comparative example may have a structure in which an insulating member is interposed between the metal film 70 and the cell region 11c as in the semiconductor device C2 of the second comparative example due to an unexpected insulating film formed on the inner surface of the source electrode groove 22 in the manufacturing process. In this case, even in the semiconductor device C1 of the first comparative example, depletion in the cell region 11c does not progress easily to thereby decrease the gate threshold voltage as in the semiconductor device C2 of the second comparative example.

For these comparative examples, in the semiconductor device 1 of this embodiment, the depletion of the cell region 11c progresses due to the action of negative fixed charges in the insulating film 45. Therefore, according to the semiconductor device 1 of this embodiment, the gate threshold voltage can be made higher than that of the semiconductor devices C1 and C2 of the comparative examples.

As shown in FIG. 4, in the semiconductor device 1 of this embodiment, it can be confirmed that a current does not easily flow through the semiconductor member 10 even if the potential of the gate electrode 53 is increased compared to the semiconductor devices C1 and C2 of the first and second comparative examples. That is, the semiconductor device 1 of this embodiment can increase the gate threshold voltage.

Next, the operations and effects of this embodiment will be described.

The semiconductor device 1 of this embodiment includes the semiconductor member 10, the drain electrode 51, the gate electrode 53, the source electrode 52, and the insulating film 45. The semiconductor member 10 is provided with the gate electrode groove 21 and the source electrode groove 22. The gate electrode groove 21 and the source electrode groove 22 are aligned in the second direction X intersecting with the first direction Y. The gate electrode groove 21 and the source electrode groove 22 are recessed toward a first side (lower side) in the third direction Z intersecting with both the first direction Y and the second direction X. The gate electrode 53 is disposed inside the gate electrode groove 21. The drain electrode 51 is located on the first side (lower side) of the semiconductor member 10 in the third direction Z. The gate electrode 53 is disposed inside the gate electrode groove 21. The source electrode 52 is disposed inside the source electrode groove 22. The insulating film 45 is provided on at least a part of the inner surface of the source electrode groove 22. The insulating film 45 contains negative fixed charges. The semiconductor member 10 is provided with the first semiconductor region 11 and the second semiconductor region 12. The first semiconductor region 11 has first conductivity type impurities. The second semiconductor region 12 has a higher concentration of first conductivity type impurities than the first conductivity type impurities of the first semiconductor region 11. The second semiconductor region 12 is located on a second side (upper side) of the first semiconductor region 11 in the third direction. The source electrode 52 can form a Schottky junction with the first semiconductor region 11. The source electrode 52 can form an ohmic junction with the second semiconductor region 12. At least a part (cell region 11c) of the first semiconductor region 11 is located between the gate electrode 53 and the source electrode 52 in the second direction X. The insulating film 45 is interposed between the part (cell region 11c) of the first semiconductor region 11 and the source electrode 52 in the second direction X.

According to this configuration, since the insulating film 45 contains negative fixed charges, the band of the first semiconductor region 11 is raised, and the depletion of the portion of the first semiconductor region 11 extending in the third direction Z along the contact portion 52b can be made significant. As a result, since the device cannot be turned on unless a large voltage is applied to the gate electrode 53, the gate threshold voltage can be increased.

In the semiconductor device 1 of this embodiment, the insulating film 45 covers the entire portion of the contact portion 52b that faces the gate electrode 53 in the second direction X.

According to this configuration, the negative fixed charges contained in the insulating film 45 raise the band of the entire portion (cell region 11c) of the first semiconductor region 11 that is sandwiched between the source electrode 52 and the gate electrode 53, and the depletion of the entire cell region 11c can be promoted. As a result, a current is unlikely to flow to the entire cell region 11c in the off state, and the gate threshold voltage can be further increased. Furthermore, in the source electrode 52 of this embodiment, the portion that faces the gate electrode 53 in the second direction X is the contact portion 52b located inside the source electrode groove 22. The insulating film 45 covers the entire portion that faces the gate electrode 53 in the contact portion 52b.

In the semiconductor device 1 of this embodiment, the metal film 70 which is a part of the source electrode 52 comes into direct contact (ohmic contact) with the second semiconductor region 12 at the end on the second side (upper end) of the source electrode groove 22 in the third direction Z. According to this configuration, a current passing through a channel formed in the cell region 11c in the on state can be made to flow to the source electrode 52 through the boundary portion where the second semiconductor region 12 and the source electrode 52 form an ohmic junction.

In the semiconductor device 1 of this embodiment, the source electrode 52 and the first semiconductor region 11 are in direct contact with each other at the bottom 22a of the source electrode groove 22. According to this configuration, the source electrode 52 and the first semiconductor region 11 form a Schottky junction, and the bottom 22a of the source electrode groove 22 can function as a diode.

In the semiconductor device 1 of this embodiment, the source electrode 52 includes the metal film 70 which is formed along the inner surface of the source electrode groove 22 and the contact portion (metal portion) 52b which is disposed inside the metal film 70. The metal film 70 can form a Schottky junction with the first semiconductor region 11. Further, the metal film 70 can form an ohmic junction with the second semiconductor region 12. The work function of the contact portion 52b is lower than the work function of the metal film 70. According to this configuration, only the metal film 70 of the source electrode 52 can be made of a member with a high work function, and the contact portion 52b can be made of a member with a low work function. Accordingly, the amount of metal with a high work function used can be reduced, and the semiconductor device 1 can be manufactured at low cost.

The semiconductor device 1 of this embodiment includes the field plate 61. The field plate 61 is provided inside the gate electrode groove 21 to be located on the lower side of the gate electrode 53 and between the gate electrode 53 and the first semiconductor region 11. The field plate 61 is insulated from the gate electrode 53 and is conductive with the source electrode 52. According to this configuration, the electric field strength in the drift region 11a of the first semiconductor region 11 can be reduced, and the withstand voltage characteristics of the semiconductor device 1 can be improved. Furthermore, in this embodiment, although a case has been described in which the semiconductor device 1 includes the field plate 61, the semiconductor device 1 may not include the field plate 61.

According to at least one of the above-described embodiments, since an insulating film is provided between the first semiconductor region 11 and the source electrode 52 capable of forming a Schottky junction with the first semiconductor region 11, depletion of the first semiconductor region 11 can be promoted, and the gate threshold voltage can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor member that includes a first groove and a second groove extending in a first direction, aligned in a second direction intersecting with the first direction, and recessed toward a first side of a third direction intersecting with both the first direction and the second direction;
a drain electrode which is located on the first side of the semiconductor member in the third direction;
a gate electrode which is disposed inside the first groove;
a source electrode which is disposed inside the second groove; and
an insulating film which is provided on at least a part of an inner surface of the second groove and contains negative fixed charges,
wherein the semiconductor member is provided with a first semiconductor region having first conductivity type impurities and a second semiconductor region having a higher concentration of the first conductivity type impurities than the first conductivity type impurities of the first semiconductor region and located on a second side of the first semiconductor region in the third direction,
wherein the source electrode is able to form a Schottky junction with the first semiconductor region and is able to form an ohmic junction with the second semiconductor region,
wherein at least a part of the first semiconductor region is located between the gate electrode and the source electrode in the second direction, and
wherein the insulating film is interposed between the part of the first semiconductor region and the source electrode in the second direction.

2. The semiconductor device according to claim 1,
wherein the insulating film covers an entire portion of the source electrode that faces the gate electrode in the second direction.

3. The semiconductor device according to claim 1,
wherein the source electrode and the second semiconductor region are in direct contact with each other at an end on the second side of the second groove in the third direction.

4. The semiconductor device according to claim 1,
wherein the source electrode and the first semiconductor region are in direct contact with each other at a bottom of the second groove.

5. The semiconductor device according to claim 1,
wherein the source electrode includes a metal film formed along an inner surface of the second groove and a metal portion disposed inside the metal film,
wherein the metal film is able to form a Schottky junction with the first semiconductor region and is able to form an ohmic junction with the second semiconductor region, and
wherein a work function of the metal portion is lower than a work function of the metal film.

6. The semiconductor device according to claim 1, further comprising:
a conductive member that is provided inside the first groove to be located on the first side of the gate electrode in the third direction and between the gate electrode and the first semiconductor region,
wherein the conductive member is insulated from the gate electrode and is conductive with the source electrode.
